(19) United States
(12) Patent Application Publication
(10) Pub. No.: US 2013/0010435 A1
(43) Pub. Date: Jan. 10, 2013

(54) FRAME UNIT, MOUNTING SUBSTRATE UNIT, AND MANUFACTURING METHOD FOR THE SAME

(76) Inventor: Toshinobu Ogatsu, Tokyo (JP)

(21) Appl. No.: 13/583,703

(22) PCT Filed: Jan. 26, 2011
(86) PCT No.: PCT/JP2011/000402

§ 371 Date: Sep. 10, 2012

(30) Foreign Application Priority Data
Mar. 11, 2010 (JP) 2010054285

(51) Int. Cl. H05K 7/14; H05K 13/00

(52) U.S. Cl. 361/748; 156/60

(57) ABSTRACT

Provided is a frame unit, a mounting substrate unit, and a mounting substrate that can achieve both high shield performance and reduction in the height of a shield member. The frame unit according to the present invention is a frame unit (100) that is attached to a substrate (200) mounted with an electronic component (210), and includes a frame member (120) with an opening 125 where the electronic component (210) is disposed and a holding member (110) that is removably attached to a top surface of the frame member (120) with the adhesive (130) interposed therebetween.

### BACKGROUND ART

In recent years, portable devices, such as a cellular phone, a Personal Digital Assistant, a notebook computer, have been widely used. In such portable devices, in addition to basic functions including an original call function, schedule management, and document creation, greater versatility has been progressing exceeding those areas. For example, functions such as transmission and reception of e-mails, web browsing, a game function, and television viewing on the mobile phone are continuously added. Consequently, the portable devices are deeply rooted as the indispensable part of life.

With such greater and sophisticated versatility, not only an antenna for communication as a telephone but an antenna for additional functions emitting different radio wave is mounted adjacently on a mobile information terminal. For example, a TV antenna, a Bluetooth antenna, a GPS (Global Positioning System) antenna, an RFID (Radio Frequency IDentification) antenna, and the like are mounted. The radio wave of different frequency is used according to usages of these antennas. Therefore, an operating clock frequency of LSI (Large Scale Integrated Circuit) increases, and it is in an extremely overcrowded state electrically. In such a state, the electronic components disposed on a printed circuit board of a Personal Digital Assistant are prone to have electrical influences mutually. Thus, a shield component for electromagnetic shielding between electronic components is needed.

On the other hand, a size of these portable devices should not be unlimitedly increased due to the nature of products to be always carried. The aforementioned increase in the size accompanying greater and more sophisticated versatility will spoil its portability, thereby not being acceptable to users. Miniaturization and reduction in the thickness is an important element for the portable terminal. Therefore, further miniaturization and reduction in the height is required for each component of the Personal Digital Assistant.

In such a situation, miniaturization and reduction in thickness have been progressing in the shield component mentioned previously. As a method of the miniaturization, instead of installing individual shield component for each functional and mounting component, the method of covering them by one shield member is often employed. This will be a large shield member integrating a plurality of shield members. Therefore, a mounting area of the shield member alone will be large. However, it is possible to reduce the mounting area necessary for the shield member as an entire mounting substrate by a reduction in the number of shield components.

Patent Literature 1 discloses a shield member that can realize the reduction in the height and a method for manufacturing a printed circuit board mounted with the same. In Patent Literature 1, as shown on the left-hand side of FIG. 11, a frame unit 10 composed of a frame member 2 and a suction member 30 is used. The frame member 2 is attached so that the suction member 30 can be removable to a frame-like frame member 2 when mounted on the printed circuit board. Then, as shown in FIG. 12, a top surface part of the suction member 30 is sucked by a suction head 7, and the frame unit 10 is mounted on a printed circuit board 5 by the suction head 7. After that, a soldering process is performed to the frame member 2. Then, the frame member 2 is physically and electrically connected to the printed circuit board 5. The suction member 30 is removed after the soldering process (center of FIG. 11). Further, a cover member 4 is attached to the frame member 2 (right-hand side of FIG. 11). Then, a shield member for electromagnetic shielding is formed.

As described above, the suction member 30 to be a suction part is made removable and separated from the frame member 2. Since it becomes unnecessary to provide the suction part in the frame member 2, the height of the frame member 2 can be reduced. It has been common to provide the suction part on the frame member 2 before the Patent Literature 1. The height in this case is the sum of the thickness of an electronic component 6, the thickness of the frame member 2 (suction part), and necessary clearance between the electronic component 6 and the suction part. Meanwhile, in Patent Literature 1, the height of the shield structure is the sum of the thickness of the electronic component 6 and necessary clearance between the electronic component 6 and the suction part. This enables the reduction in the height of the shield structure.

Further, as shown in FIG. 13, a step 31 is formed on the top surface of the suction member 30, and the step part is sucked to be mounted on the printed circuit board. Then, the aforementioned necessary clearance between the electronic component 6 and the suction part can be moved toward the suction member 30 side. This enables further reduction in the height of the frame member 2. Specifically, the height of the frame member 2 can be set to be equivalent to the height of the electronic component 6 mounted inside the frame.

In general, the suction member 30 is manufactured by bending a thin metal plate such as stainless and nickel silver into a predetermined shape. The suction member 30 and the frame member are also held by concavo-convex shape. That is, a projection is provided at a predetermined position on the side wall of one member and a hole is provided at a position corresponding to the aforementioned projection on the side wall of the other member. Then, they are mated so that the suction member holds the frame member. The strength of the mating part (load of the suction member 30 to hold the frame member 2) largely depends on the elastic force of the side wall of the suction member 30. As the material of the suction member 30 is metal, it does not separate easily.

### CITATION LIST

### Patent Literature

Patent Literature 1: Japanese Unexamined Patent Application Publication No. 2008-34713

### SUMMARY OF INVENTION

### Technical Problem

However, in the shield member disclosed in Patent Literature 1, there is an issue of productivity fall by further reduction in the thickness and increase in the area.

As mentioned above, the shield member is composed of the frame member and the cover member. Increasing the size of these members with the same plate thickness generates a reduction in the strength of each member. Moreover, reducing the thickness with the fixed plate thickness causes a reduction in the section modulus, thereby leading to the reduction in the strength. The reduction in the strength could result in proneness to failures such as deformation in a manufacturing process of the components. This is not the only consequence but proneness to deformation in the following manufacturing process including transfer and mounting is also caused. The deformation in the components induces poor soldering at the stage of mounting. Accordingly, there is a possibility that the shielding function cannot be realized, which is an original purpose. Further, the suction member used in Patent Literature 1 has a structure that elastically deforms and fixed to the frame member. Therefore, there is a possibility of causing the deformation in the frame member also by such a suction member.

A purpose of the present invention is made in view of the above problem and is to provide a frame unit, a mounting substrate unit, and a manufacturing method for the same with high productivity.

### Solution to Problem

An exemplary aspect of the present invention is a frame unit that is attached to a mounting substrate mounted with an electronic component, and includes a frame member with an opening where the electronic component is disposed and a holding member that is removably applied on a top surface of the frame member with an adhesive interposed therebetween.

Another exemplary aspect of the present invention is a manufacturing method for a mounting substrate unit that is mounted with an electronic component and a frame member surrounding the electronic component, and includes a step of preparing a frame member with an opening where the electronic component is disposed, a step of attaching a holding member to the frame member with an adhesive interposed therebetween, a step of holding the holding member by a holding mechanism and disposing the frame member on a substrate, a step of connecting the frame member to the substrate, and a step of removing the holding member from the frame unit.

### Advantageous Effects of Invention

According to the present invention, it is possible to provide a frame unit, a mounting substrate unit, and a manufacturing method thereof with high productivity.

### BRIEF DESCRIPTION OF DRAWINGS

FIG. 1 is a perspective view showing a configuration of a mounting substrate unit according to a first exemplary embodiment of the present invention;

FIG. 2 is an exploded view showing a configuration of a frame unit used in the mounting substrate unit;

FIG. 3 is a side view showing the configuration of the mounting substrate unit according to the first exemplary embodiment of the present invention;

FIG. 4 is a cross-sectional side view showing the configuration of the mounting substrate unit according to the first exemplary embodiment of the present invention;

FIG. 5 is a diagram for explaining a manufacturing process of the mounting substrate unit;

FIG. 6 is a side view showing the mounting substrate unit according to the first exemplary embodiment of the present invention;

FIG. 7 is a side view showing the configuration of the mounting substrate unit according to the exemplary embodiment of the present invention;

FIG. 8 is a perspective view showing a configuration of a holding member according to another exemplary embodiment;

FIG. 9 is a perspective view showing a configuration of a frame member according to the another exemplary embodiment;

FIG. 10 is a cross-sectional side view showing the configuration of the frame member according to the another exemplary embodiment;

FIG. 11 is a perspective view showing a configuration of a mounting substrate according to Patent Literature 1;

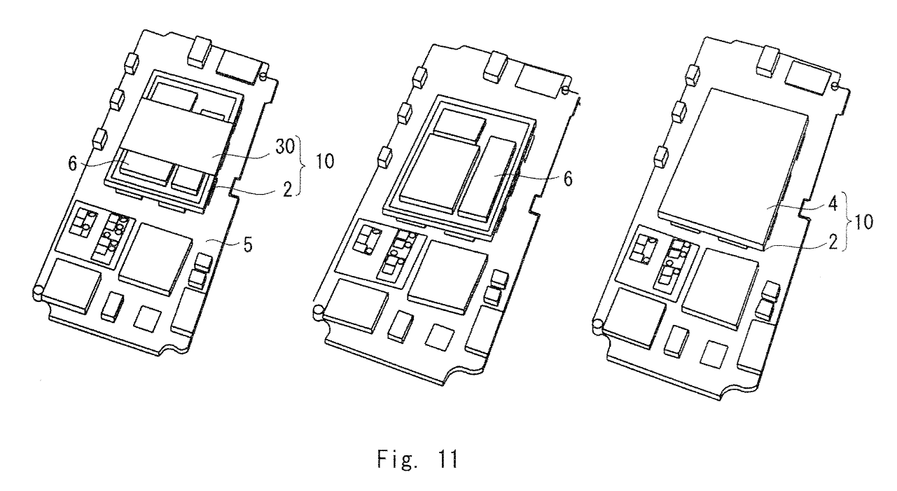

FIG. 12 is a cross-sectional side view showing a configuration of a mounting frame unit according to Patent Literature 1; and

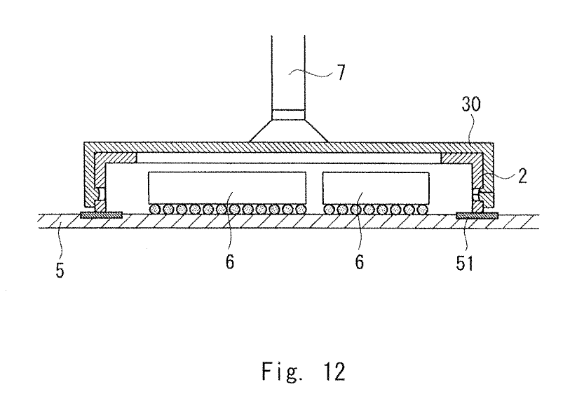

FIG. 13 is a diagram showing another configuration of the mounting frame unit according to Patent Literature 1.

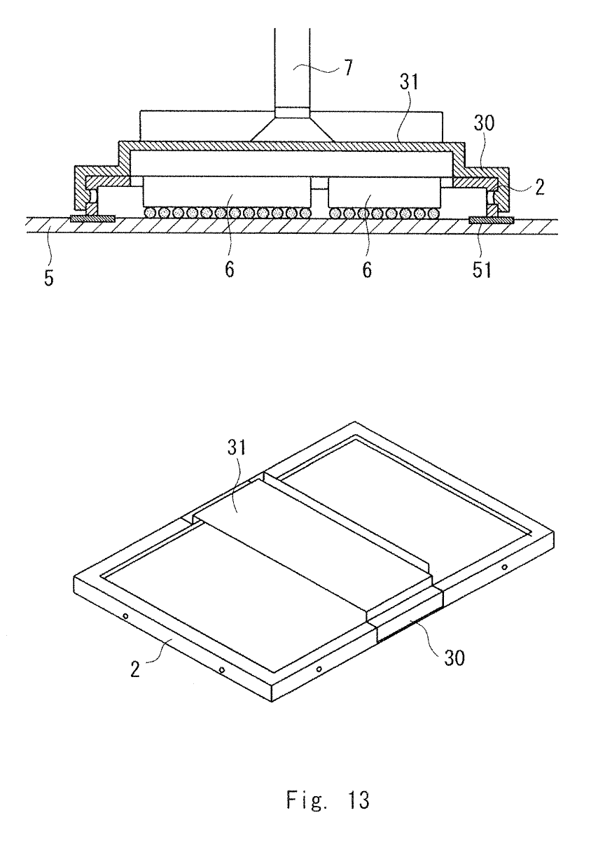

### DESCRIPTION OF EMBODIMENTS

Hereinafter, an example of an exemplary embodiment incorporating the present invention is explained. Note that the size and ratio of each member in the following drawings are for the convenience of the explanation and do not necessary match the actual ones.

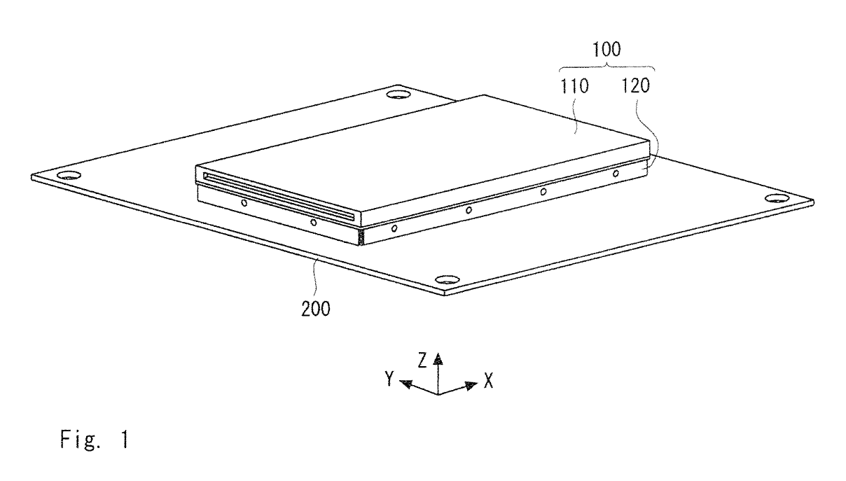

An external view of a mounting substrate unit according to an exemplary embodiment of the present invention is shown in FIG. 1. FIG. 1 is a perspective view showing a mounting substrate unit used for portable devices such as a mobile phone, for example. Note that the structure in which a frame member 120 is attached to a mounting substrate including electronic components mounted thereon is referred to as a mounting substrate unit. Note that in the following explanation, a three-dimensional orthogonal coordinate system is used to simplify the explanation. As shown in FIG. 1, assume that a thickness direction of a substrate 200 shall be a Z direction and a direction parallel to an edge end of the substrate 200 shall be an XY direction. Note that in the following explanation, the Z direction is referred to as a vertical direction (height direction) and the XY direction is referred to as a horizontal direction.

The mounting substrate unit includes a substrate 200 and a frame unit 100. The substrate 200 is a printed circuit board, for example, and wiring and the like for connecting to the electronic components are formed thereon. A frame unit 100 includes a frame member 120 and a holding member 110. The frame unit 100 will be a temporary assembling component for mounting the shield structure to an electronic substrate. For example, the frame member 120 of the frame unit 100 is connected to the substrate 200. Then, the holding member 110 is attached to the frame member 120. Further, the electronic components (not shown in FIG. 1) are disposed inside the frame unit 100. Note that the frame member 120 is formed in the shape of a frame to surround the electronic components. Then, in practical use, the holding member 110 is removed from the frame member 120, and a shield cover is attached. Therefore, the holding member 110 is a temporary cover member not used in practice.

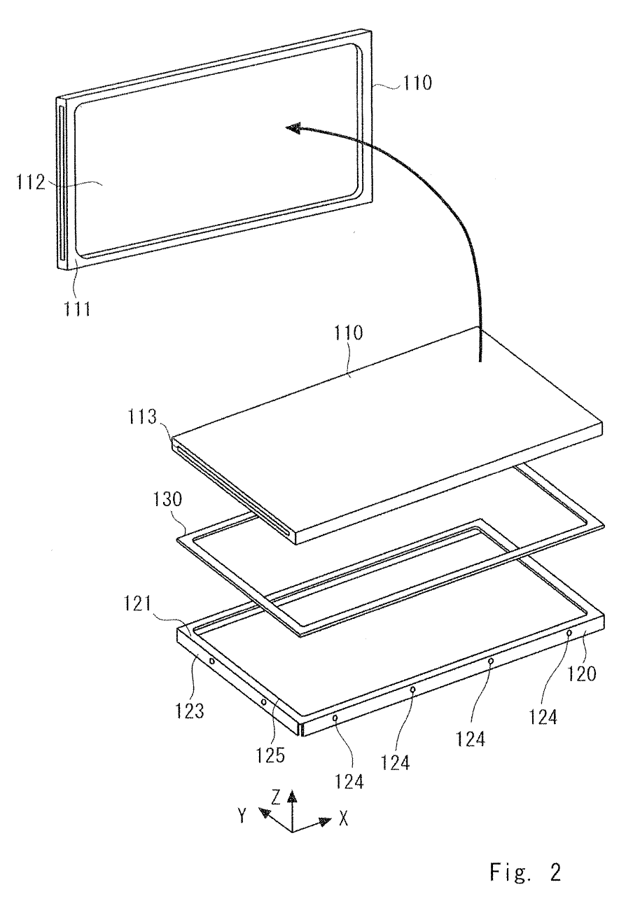

Next, a configuration of the frame unit 100 is explained using FIG. 2, which is an exploded perspective view showing the configuration of the frame unit. As shown in FIG. 2, the frame member 120 is formed in a frame shape. Each edge of the frame-shaped frame member 120 is disposed in parallel to the X direction or the Y direction. The frame member 120 includes a top surface part 121, side walls 123, projections 124, and an opening 125.

The frame member 120 includes the opening 125 for making the electronic component visible when the holding member 110 is removed. Specifically, the side wall 123 is provided to define the opening 125. The side wall 123 will be a frame disposed outside the electronic component. Two side walls 123 extending in the X direction and two side walls 123 extending in the Y direction are coupled to form the rectangular frame shaped frame member 120. The height of the side wall 123 corresponds to the height of the electronic component to be mounted. The upper surface of the side wall 123 shall be the top surface part 121. That is, the opposite surface to the substrate 200 of the side wall 123 is the top surface part 121.

The projections 124 are formed outside the side walls 123. The projections 124 are formed in order to attach the shield cover described later. The projections 124 are disposed on side surfaces of the side walls 123, for example. For example, four projections 124 are formed on the side wall 123 in the X direction and two projections 124 are formed on the side wall 123 in the Y direction. The top surface part 121 is provided on the upper side of the side surface 123.

Moreover, the frame unit 100 includes an adhesive 130 for bonding the holding member 1 and the frame member 120. Specifically, the holding member 110 is bonded to the frame member 120 with the adhesive 130 interposed therebetween. The adhesive 130 is a double-faced adhesive sheet, for example, and has a shape corresponding to the side wall 123. A frame shaped adhesive sheet is used for the adhesive 130. Therefore, an opening is formed in the adhesive sheet to be the adhesive 130 corresponding to the shape of the opening 125. The lower surface of the adhesive 130 is bonded to the top surface part 121, and the top surface of the adhesive 130 is bonded to the lower surface of the holding member 110 (an adhesive surface 111). Then, the holding member 110 is fixed to the frame member 120. Since the external dimensions of the frame member 120 and the external dimensions of the holding member 110 are the same, it is possible to perform positioning from outward shape to be fixed.

The adhesive 130 is desirably a heat-resistant silicone gel sheet or a heat-peelable pressure-sensitive adhesive sheet (product name: Revalpha, manufactured by Nitto Denko Corporation). In the case of the heat-resistant silicone gel sheet, there are advantages such as reflow heat resistance in the post process, and repeated adhesion, thereby not leading to any change in the resin state before and after being heated. As described above, the heat-resistant silicone gel sheet has an advantage of repeated adhesion. That is, there is a reflow process in the post process during the manufacturing process of the mounting substrate unit. The heat-resistant silicone gel sheet has reflow heat resistance and there is no change in the resin state before and after being heated. Then, the heat resistant silicone gel sheet, which is the adhesive 130, can be reused. Thus, the productivity can be improved.

Note that the heat resistance here indicates that the adhesive force of the adhesive 130 is maintained before and after the reflow process. In other words, no change in the adhesive force before and after the reflow process is referred to as the heat resistance.

On the other hand, the heat-peelable pressure-sensitive adhesive sheet has advantages such as easy removal after reflow and not being prone to an influence of heat deformation in the holding member 110 during the reflow process as the pressure-sensitive adhesive force is reduced by heat. In any case, it is important to select the one with small pressure-sensitive adhesive residue on the top surface part 121 of the frame 120 after the reflow process.

The holding member 110 is a plate-like member that covers the opening 125 and a recess 112 is formed in the lower side. The size of this recess 112 corresponds to the opening 125. Then, the adhesive surface 111 disposed on the outside part of the recess 112 is bonded to the adhesive 130. The adhesive surface 111 has a shape corresponding to the top surface part 121 of the side wall 123. The flatness of the adhesive surface 111 of the holding member 110 is preferably 100 μm or less, for example. This improves the adhesiveness and secures fixing to the adhesive 130.

A molded resin product, for example, can be used as the holding member 110. For example, it is desirable to use resin suitable for reflow heat resistance and precision molding. Specifically, polyphenylene sulfide resin (PPS) can be used. Needless to say that metal can be used for the holding member 110.

Additionally, grooves 113 are formed on the side surface of the holding member 110. The grooves 113 are formed on the opposing two side surfaces. The holding member 110 is removed from the frame member 120 by hooking tabs on these grooves 113 as described later. This process is described later.

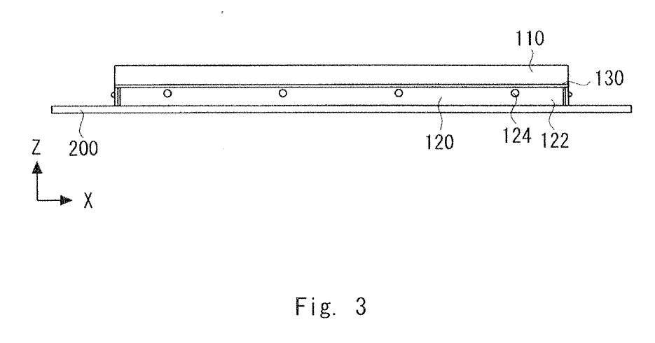

As shown in FIG. 3, the frame member 120 is mounted on the substrate 200. The holding member 110 is attached on the frame member 120. The adhesive 130 is provided between the frame member 120 and the holding member 110. This fixes the holding member 110 to the frame member 120. Then, the opening of the frame member 120 is covered by the holding member 110. Further, holding the holding member 110 by a holding mechanism allows the frame member 120 to move to a predetermined position.

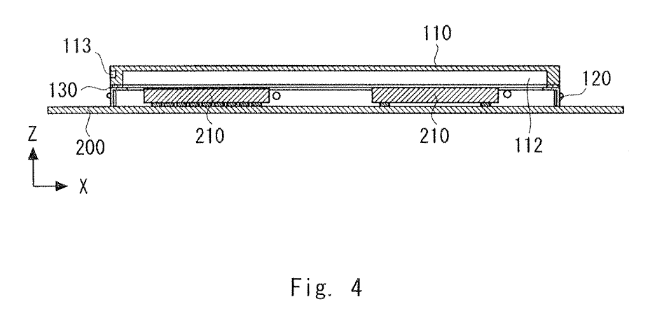

As shown in FIG. 4, electronic components 210 are mounted on the substrate 200. The electronic components 210 are disposed in the opening of the frame member 120. That is, the electronic components 210 such as an IC are mounted on a position visible from the opening 125. Moreover, a plurality of electronic components 210 including different functions are mounted in the frame member 120. The recess 111 formed in the holding member 110 widens the space below the holding member 110. The recess 111 is formed to a position where the electronic components 210 are mounted on the substrate 200. That is, the recess 111 is disposed immediately above the electronic components 210. This accordingly widens the space to mount the electronic components 210. Therefore, the height of the frame member 120 can be reduced.

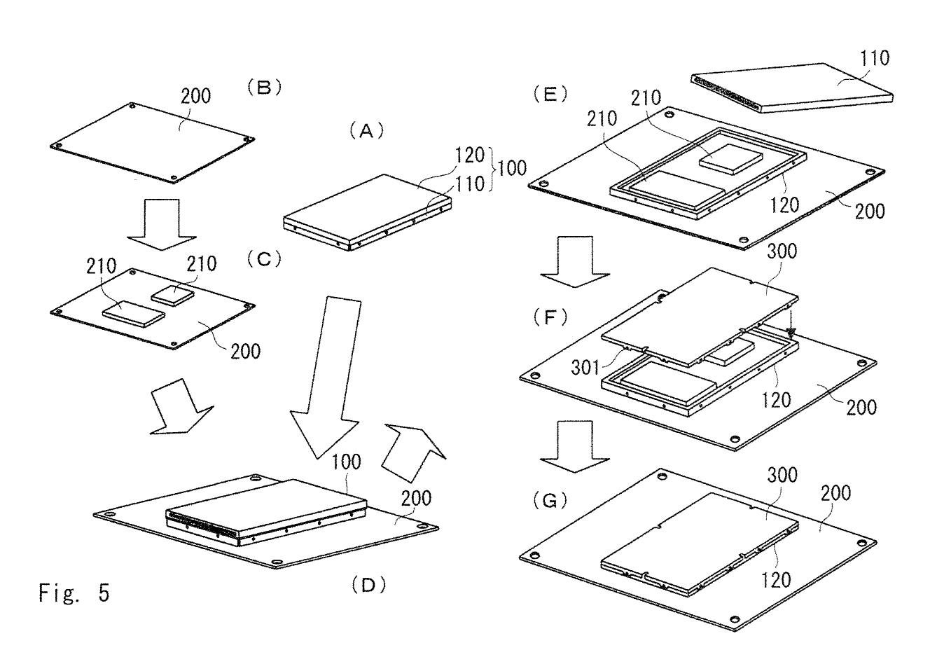

In this way, the recess 112 is formed to avoid contact with the electronic components 210 that are mounted on the substrate 200. Forming this recess 112 creates larger clearance from the electronic components 210 (FIG. 5). Note that after the holding member 110 is bonded to the frame member 120 and at the time of mounting them on the substrate 200, the electronic components 210 are already attached to the substrate 200. The electronic components 210 are semiconductor components such as a semiconductor chip. The clearance from the electronic components 210 increases by the recess 112.

As shown in FIG. 5, the height Hb of the electronic components should be lower than the height Ha of the shield frame by dimension tolerance (usually about 0.1 mm) before and after mounting. Even in this way, the electronic components 210 and the shield cover do not interfere when the shield cover is assembled eventually. This enables further reduction in the height. Moreover, since the load applied to the side wall 123 in the horizontal direction can be reduced, it is possible to prevent deformation in the frame member 120. Therefore, the productivity can be improved.

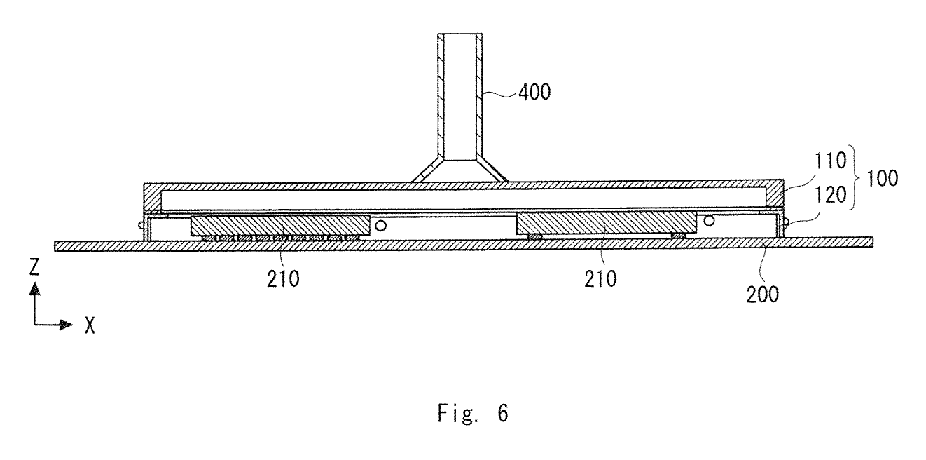

Next, a manufacturing method of the mounting substrate is explained using FIG. 6. FIG. 6 is a diagram schematically showing the manufacturing process (A to G) of the mounting substrate and is a perspective view of a configuration in each process.

First, the frame unit 100 including the frame member 120 and the holding member 110 is prepared. That is, the adhesive 130 is applied to the top surface part 121 of the side wall 123 of the frame member 120. Then, the holding member 110 is applied to the frame member 120 on the adhesive 130. This integrates the frame member 120 and the holding member 120 with the adhesive 130 interposed therebetween and forms the frame unit 100. At this time, positioning is performed by an external form of the frame member 120. Note that the adhesive 130 can be firmly bonded to the side of the holding member 110. That is, the order of applying the adhesive 130 is not especially limited, and the adhesive member 110 and the adhesive 130 may be applied first.

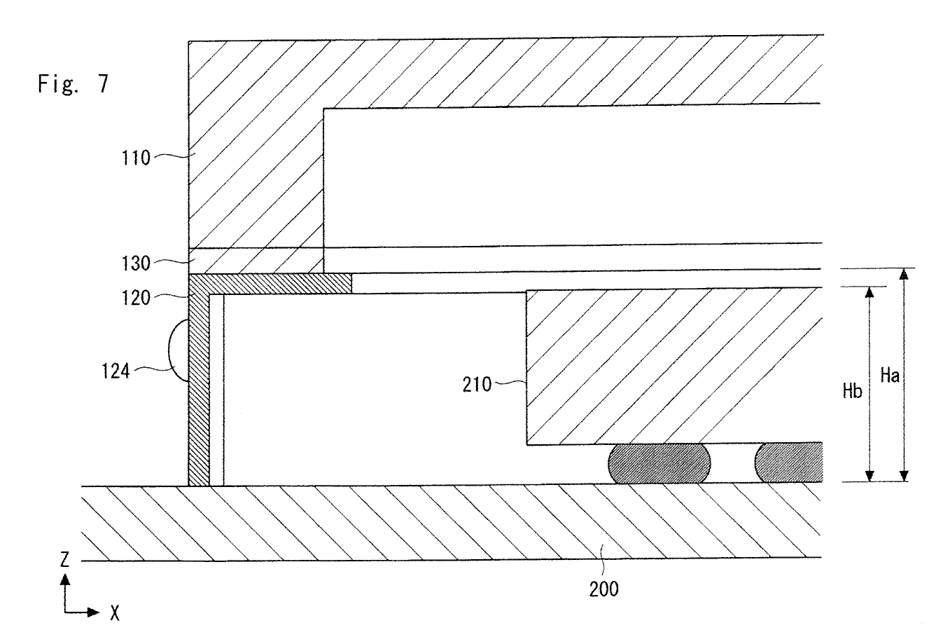

Subsequently, precision solder printing using a metal mask (not shown) is performed to the substrate 200 and the electronic components 210 are mounted (B to C). Specifically, the electronic components 210 are mounted on the part where the solder (not shown) is applied. Further, the frame unit 100 is mounted on the substrate 200 (D). The holding mechanism such as a suction nozzle 400 is used here as shown in FIG. 7. That is, holding the holding member 110 by the holding mechanism allows the frame member 120 to be disposed on the substrate 200. The frame unit 100 can be mounted using suction by being picked and placed using a general-purpose mounting device. Thus, a special device and a jig are not necessary in particular.

Fusion bonding of solder by the reflow process is performed to the substrate 200 that is mounted with the electronic components 210 and the frame unit 100. At this time, in the configuration disclosed in Patent Literature 1, the frame member 120 and the holding member 110 overlap on the surface of the side wall. Accordingly, along with the reduction in the height of the frame member 120, the lower end position of the holding member 110 may drop and solder wicking may occur on the overlapped part. On the other hand, according to the configuration of this exemplary embodiment, as the frame member and the temporal cover member are fixed on the top surface, such a situation can be avoided. This reduces the height of the frame member 120.

Moreover, advances in elimination of lead results in higher melting point of the solder. Tin-solder-copper solder, which has been used as the precision instruments, is heated up to around 240 degrees Celsius in the reflow process. The heat-resistant silicone gel mentioned before excels in the reflow heat-resistance at 240 degree Celsius. In the case where this heat-resistant silicone gel sheet is used as the adhesive 130, gas will not be emitted from resin in the reflow process and the adhesive 130 will not melt and be unable to be peeled. Therefore, the frame member 120 and the holding member 110 can be firmly fixed.

Further, in the case where the heat peelable sheet is used as the adhesive 130, it has the nature that the pressure-sensitive adhesive force is reduced by more than certain heat. That is, the adhesive force is reduced upon reaching a certain temperature. Thus, the adhesive force is reduced by the heat during the reflow process, thereby separating the frame member 120 and the holding member 110 or enabling easy separation in the following process. Then, the productivity can be improved. The reflow process makes the frame member 120 of the frame unit 100 be soldered and firmly fixed to the substrate 200 after soldering is completed.

In this state, the holding member 110 is removed from the frame member 120 (E). Specifically, tabs of a removal jig are hooked on the grooves 113 formed on the side surface of the holding member 110 to be held upward. Then the holding member 110 is peeled from the flame member 120. Note that when the heat peelable sheet is used as the adhesive 130, the pressure-sensitive adhesive force of the adhesive 130 is already reduced by the heat during the reflow process. Therefore, the holding member 110 can be separated extremely easily. Thus the productivity can be improved. Similarly, the heat peelable adhesive that can be peeled by heating may be employed. As the main components of the adhesive, there are modified epoxy resin and modified polyamidoamine.

A shield cover 300 is attached to the frame member 120 with the holding member 110 being removed (F to G). The shield cover 300 is fit from above into the frame member 120 (F). Holes 301 that mate with the projections 124 are formed on the side surface of the shield cover 300. Mating the projections 124 of the frame member 120 and the holes 301 of the shield cover 300 electrically and mechanically connects the frame member 120 and the shield cover 300, thereby completing the shield structure.

The holding member 110 is sucked by the suction nozzle 400 at the time of being picked and placed by the mounting machine during these processes as shown in FIG. 7. That is, holding the frame unit 100 by the suction nozzle, which is the holding mechanism, allows the frame member 120 to move. The vicinity of the center part of the holding member 110 must be configured to be resistant to suction. In other words, there should not be any notch or defect in the corresponding part of the holding member 110.

Note that the adhesive 130 may be used to fix the shield cover 300 and the frame member 120. That is, the shield cover 300 is bonded to the frame member 120 with the adhesive 130 interposed therebetween. For example, a conductive adhesive sheet is used as the adhesive. In this case, the projections 124 and the holes 301 become unnecessary. Needless to say that the adhesive 130 may be used to fix together with the mating structure of the projections 124 and the hole 301. Note that when the adhesive 130 is used, it is preferable to use the heat-resistant adhesive 130. This prevents the adhesive force from being reduced by the reflow process.

At the time when the frame member 120 with an opening at the center is mounted, the adhesive 130 is applied to the top surface part 121 of the frame member 120. The frame unit 100 with the holding member 110 bonded thereto with the adhesive 130 interposed therebetween is manufactured. Using the one with heat resistance to the heat during reflow for both of the holding member 110 and the adhesive 130 allows mounting of the frame unit 100 in a similar manner as the electronic components 210. After mounting, soldering is performed by the reflow process, and then the holding member 110 is removed from the frame member 120. This can stabilize the shape of the frame member 120, which has been destabilized by the increase in the size. Then, failures upon mounting can be reduced and high productivity can be achieved.

There will be no deformation in the frame member 120 when the holding member 110 is attached. This eliminates the need to consider the deformation in the frame member 120 after the holding member 110 is attached. As a result, frame rigidity design for attaching the holding member 110 will be unnecessary. Therefore, while the flexibility of the shape increases, it is possible to thin, reduce the height of, and increase the area of the frame member 120.

As the component rigidity at the time of mounting depends on the holding member 110, it is possible to thin, reduce the height of, and increase the area of the frame member 120 without considering to retain the shape at the time of mounting. The holding member 110 is designed to have higher rigidity than the frame member 120, thereby creating a less deformable shape. Further, the bonded surface with the frame member 120 of the holding member 110 is completed with high flatness. Bonding the frame member 120 to the holding member 110 enables correction of the deformation in the frame member 120. The shape of the frame member 120 depends on the shape of the holding member 110 before and after mounting. Therefore, it is a point that that flatness of the frame member 120 itself does not need to be considered.

Bonding the frame member 120 to the top surface is used as a method to bond the holding member 110 to the frame member 120. This allows easy removal of the holding member 110 from the frame member 120 after being soldered. When the heat peelable adhesive material is used that have reduced adhesive force upon application of heat, the adhesive force of the adhesive 130 is reduced during reflow in the reflow process after mounting. Accordingly, easy removal can be made possible.

In the abovementioned explanation, although the temporary cover component is explained to be heat-resistant resin, metal material such as aluminum alloy, stainless steel, titanium, magnesium alloy, and zinc alloy may be used. In this case, when only a small number is required, it can be manufactured by machining. Alternatively, when high volume production is required, it can be manufactured by methods such as die-casting and thixomolding and also a metal injection method. The metallization increases the cost, but also increases durability under repeated use. Thus, it is possible to select which one is better in terms of the total cost. Then, the productivity can be improved.

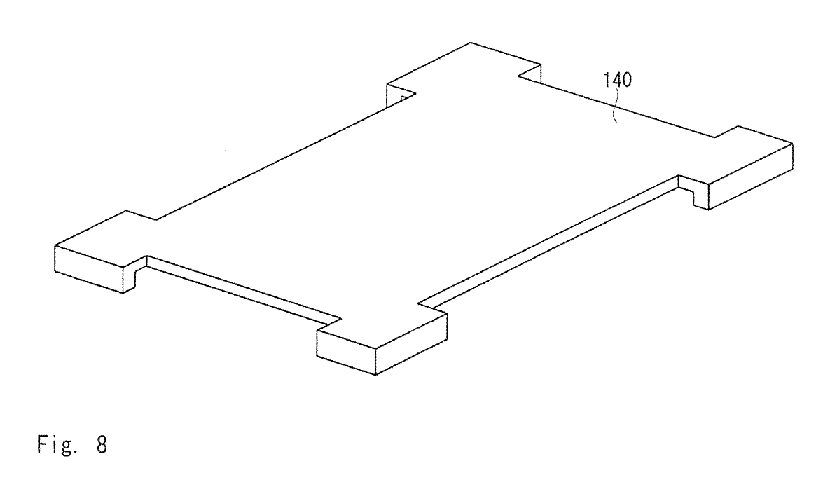

Further, as shown in FIG. 8, the shape of the holding member 140 does not necessarily need to be the same as the external form of the frame member 120. As shown in FIG. 8, cutting out four corners reduces the adhesion area but enables direct confirmation of the position of the frame member 120 at the time of mounting the component. Therefore, it is possible to suppress displacement more than in the case of having the same shape when the position of the holding member is recognized to be mounted. In other words, the displacement on the substrate 200 can be suppressed by the positioning accuracy of the holding member and the frame member.

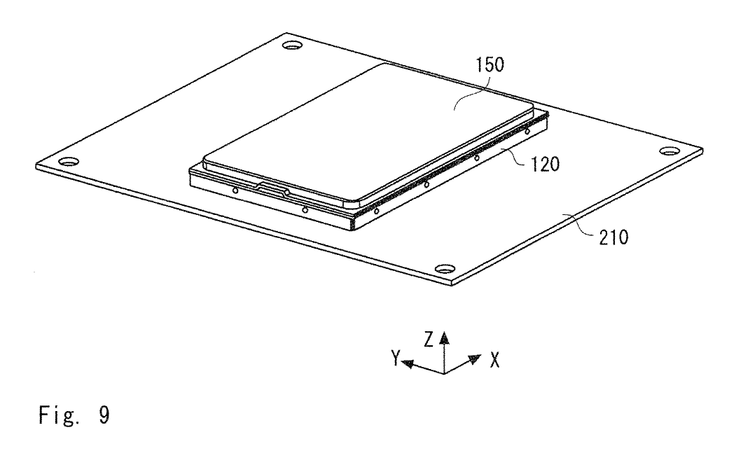

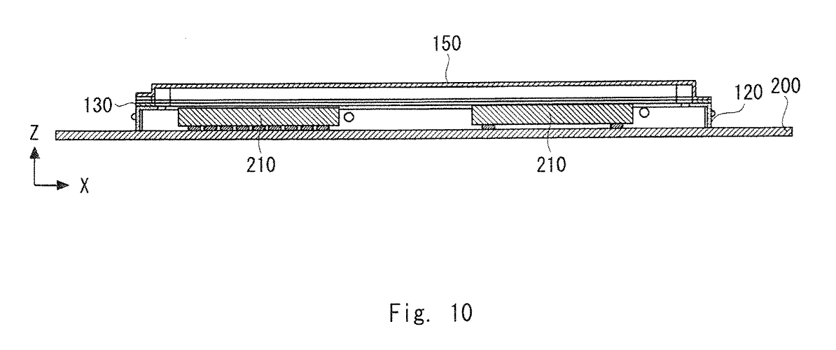

Moreover, the holding member 150 can be manufactured by press working as shown in FIGS. 9 and 10. FIG. 9 is a perspective view showing a mounting substrate with the holding member 150 mounted thereon which is manufactured by press working. FIG. 10 is a cross-sectional view showing a mounting substrate unit with the holding member 150 mounted thereon which is manufactured by press working. Using press working in this way realizes the structure in which the parts do not easily interfere. In addition, press working facilitates to achieve the flatness of the bonded surface and increases the strength unlike simple folding. This sufficiently deals with suppression of the deformation in the frame member 120. Moreover, the holding member 150 is abandoned or reused, and will not remain mounted on the mounting substrate at the end in any way. Therefore, the plate thickness may be increased to increase the strength.

In this way, it is possible to provide a mounting process with high productivity that suppresses the deformation in the frame member 120. The temporary cover member is attached to the top surface of the frame member 120 immediately after the frame member 120 is manufactured or till the previous stage of mounting the frame member 120. It is mounted by an automatic mounting machine on the solder-printed substrate and soldered in the reflow process together with other mounting components. After the frame member is firmly soldered to the substrate, the temporary cover component is removed. Such a process enables attachment without deforming the frame member upon attaching the temporary cover member to the frame member and achieves a component structure with high rigidity as the temporary cover member does not need to be thinned. Design for higher strength, rigidity, and surface precision of the bonded surface than the frame member also enables correction of the deformation in the frame member. Further, removal without the deformation in the frame member can be made possible upon removal after mounting. As a result, it is possible to realize miniaturization and reduction in the thickness of the frame member with high productivity.

Note that as described above, although it is preferable to use a sheet adhesive as the adhesive 130, a paste adhesive may be used.
(Supplementary note 1) A frame unit that is attached to a mounting substrate mounted with an electronic component, the frame unit comprising:

a frame member including an opening where the electronic component is disposed; and

a holding member that is removably applied on a top surface of the frame member with an adhesive interposed therebetween.
(Supplementary note 2) The frame unit according to Supplementary note 1, wherein the adhesive is a heat-peelable adhesive sheet with adhesive force reduced upon application of heat.
(Supplementary note 3) The frame unit according to Supplementary note 1, wherein the adhesive includes heat resistance.
(Supplementary note 4) The frame unit according to one of Supplementary notes 1 to 3, wherein the holding member is formed of heat-resistant resin or metal.
(Supplementary note 5) The frame unit according to one of Supplementary notes 1 to 4, wherein a groove is formed on a side surface of the holding member.
(Supplementary note 6) A mounting substrate unit comprising: the frame unit according to one of Supplementary notes 1 to 5;

a substrate that is mounted with the frame unit; and

an electronic component that is mounted on the substrate in the opening of the frame member of the frame unit.
(Supplementary note 7) A manufacturing method for a mounting substrate unit that is mounted with an electronic component and a frame member surrounding the electronic component, the manufacturing method comprising:

a step of preparing a frame member that includes an opening where the electronic component is disposed;

a step of attaching a holding member to the frame member with an adhesive interposed therebetween;

a step of holding the holding member by a holding mechanism and disposing the frame member on a substrate;

a step of connecting the frame member to the substrate; and

a step of removing the holding member from the frame unit.
(Supplementary note 8) The manufacturing method for the mounting substrate unit according to Supplementary note 7, wherein in the step of connecting the frame member to the substrate, a reflow process is used and adhesive force of the adhesive is reduced by a temperature of the reflow process.
(Supplementary note 9) The manufacturing method for the mounting substrate according to Supplementary note 7, wherein in the step of connecting the frame member to the substrate, a reflow process is used and adhesive force of the adhesive is maintained before and after the reflow process.
(Supplementary note 10) The manufacturing method for the mounting substrate unit according to one of Supplementary notes 7 to 9, further comprising a step of attaching a shield cover to the frame member after the holding member is removed, wherein

The shield cover is attached to the frame member by the adhesive with conductivity.

0(Supplementary note 11) The manufacturing method for the mounting substrate unit according to one of Supplementary notes 7 to 10, wherein in the step of removing the holding member, the holding member is removed by hooking a tab on a groove provided on a side surface of the holding member.
(Supplementary note 12) The frame unit according to one of Supplementary notes 7 to 11, wherein the holding member is formed of heat-resistant resin or metal.

Although the present invention has been described with reference to the exemplary embodiments, the present invention is not limited by above. Various modifications that can be understood by the person skilled in the art can be made to the configurations and details of the present invention within the scope of the invention.

The present application claims priority rights of and is based on Japanese Patent Application No. 2010-54285 filed on Mar. 11, 2010 in the Japanese Patent Office, the entire contents of which are hereby incorporated by reference.

### INDUSTRIAL APPLICABILITY

The present invention can be suitably applied to a mounting substrate and a frame unit in a mobile terminal and the like.

### REFERENCE SIGNS LIST

100 FRAME UNIT
110 HOLDING MEMBER

0111 ADHESIVE SURFACE
112 RECESS
120 FRAME MEMBER
121 TOP SURFACE PART
123 SIDE WALL
124 PROJECTION
125 OPENING
130 ADHESIVE
200 MOUNTING SUBSTRATE
210 ELECTRONIC COMPONENT

1. A frame unit that is attached to a mounting substrate mounted with an electronic component, the frame unit comprising:
a frame member including an opening where the electronic component is disposed; and
a holding member that is removably applied on a top surface of the frame member with an adhesive interposed therebetween.

2. The frame unit according to claim 1, wherein the adhesive is a heat-peelable adhesive sheet with adhesive force reduced upon application of heat.

3. The frame unit according to claim 1, wherein the adhesive includes heat resistance.

4. The frame unit according to claim 1, wherein the holding member is formed of heat-resistant resin or metal.

5. The frame unit according to claim 1, wherein a groove is formed on a side surface of the holding member.

6. A mounting substrate unit comprising:
the frame unit according to claim 1;
a substrate that is mounted with the frame unit; and
an electronic component that is mounted on the substrate in the opening of the frame member of the frame unit.

7. A manufacturing method for a mounting substrate unit that is mounted with an electronic component and a frame member surrounding the electronic component, the manufacturing method comprising:
a step of preparing a frame member that includes an opening where the electronic component is disposed;
a step of attaching a holding member to the frame member with an adhesive interposed therebetween;
a step of holding the holding member by a holding mechanism and disposing the frame member on a substrate;
a step of connecting the frame member to the substrate; and
a step of removing the holding member from the frame unit.

8. The manufacturing method for the mounting substrate unit according to claim 7, wherein in the step of connecting the frame member to the substrate, a reflow process is used and adhesive force of the adhesive is reduced by a temperature of the reflow process.

9. The manufacturing method for the mounting substrate according to claim 7, wherein in the step of connecting the frame member to the substrate, a reflow process is used and adhesive force of the adhesive is maintained before and after the reflow process.

10. The manufacturing method for the mounting substrate unit according to claim 1, further comprising a step of attaching a shield cover to the frame member after the holding member is removed, wherein the shield cover is attached to the frame member by the adhesive with conductivity.
